(19) United States
(12) Patent Application Publication
(10) Pub. No.: US 2025/0306268 A1
(43) Pub. Date: Oct. 2, 2025

(54) SEMICONDUCTOR PACKAGE

(71) Applicant: Samsung Electronics Co., Ltd., Suwon-si (KR)

(72) Inventors: Seok Geun AHN, Suwon-si (KR); Juhyeon OH, Suwon-si (KR)

(73) Assignee: Samsung Electronics Co., Ltd., Suwon-si (KR)

(21) Appl. No.: 18/931,203

(22) Filed: Oct. 30, 2024

(30) Foreign Application Priority Data
Apr. 2, 2024 (KR) 10-2024-0044931

(51) Int. Cl. G02B 6/122; G02B 6/12; H01L 23/31; H01L 23/498; H01L 23/538; H01L 25/00; H01L 25/16

(52) U.S. Cl. CPC G02B 6/122; H01L 25/167; G02B 2006/12061; H01L 23/3135; H01L 23/49816; H01L 23/5385; H01L 25/50

(57) ABSTRACT

A semiconductor package may include an optical integrated circuit including a coupler, an electronic integrated circuit connected to the optical integrated circuit, a transfer structure in contact with an upper surface of the optical integrated circuit, and a connection on the transfer structure. The connection may guide structures extending in a first direction, and spaced apart from each other in a second direction perpendicular to the first direction, an adhesive member between the guide structures, and a connection portion at least partially surrounded by the adhesive member. The adhesive member may include a waveguide portion between sidewalls of the guide structures that face each other, and the waveguide portion may be connected to the adhesive member.

### CROSS-REFERENCE TO RELATED APPLICATIONS

This U.S. non-provisional patent application claims priority under 35 U.S.C. § 119 of Korean Patent Application No. 10-2024-0044931, filed on Apr. 2, 2024, the entire contents of which are hereby incorporated by reference.

### BACKGROUND

At least some example embodiments relate to a semiconductor package, for example to a semiconductor package including an optical structure.

Demand for miniaturization and speed of electronic devices is increasing. Accordingly, active research for replacing signal transmission through a typical metal line with signal transmission using an optical signal is being conducted. Accordingly, a semiconductor package including an optical integrated circuit in which a light source, an optical coupling element, and the like are integrated may be advantageous and/or desired to transmit optical signals.

### SUMMARY

The present inventive concepts relate to a semiconductor package with improved electrical characteristics.

According to some example embodiments of inventive concepts a semiconductor package may include an optical integrated circuit including a coupler, an electronic integrated circuit connected to the optical integrated circuit, a transfer structure in contact with an upper surface of the optical integrated circuit, and a connection on the transfer structure, wherein the connection includes guide structures extending in a first direction, and spaced apart from each other in a second direction, the second direction perpendicular to the first direction, an adhesive member between the guide structures, and a connection portion at least partially surrounded by the adhesive member, the adhesive member includes a waveguide portion between sidewalls of the guide structures that face each other, and the waveguide portion is connected to the transfer structure.

According to some example embodiments of inventive concepts, a semiconductor package may include an optical integrated circuit including a coupler, an electronic integrated circuit connected to the optical integrated circuit, a transfer structure on the optical integrated circuit, and a connection on the transfer structure, wherein the connection includes guide structures extending in a first direction, an adhesive member between the guide structures, and a connection portion at least partially surrounded by the adhesive member, and the transfer structure includes a semiconductor material, and is in contact with an upper surface of the optical integrated circuit and a lower surface of the guide structure.

In some example embodiments of inventive concepts, a semiconductor package may include a first solder ball, an interposer substrate on the first solder ball, a semiconductor chip mounted on the interposer substrate, and an optical structure spaced apart from the semiconductor chip, and on the interposer substrate, wherein the optical structure includes a second solder ball, a reline substrate on the second solder ball, an optical integrated circuit on the reline substrate, an electronic integrated circuit connected to the optical integrated circuit, a transfer structure in contact with an upper surface of the optical integrated circuit, and a connection on the transfer structure, the connection includes guide structures extending in a first direction, and spaced apart from each other in a second direction, the second direction perpendicular to the first direction, an adhesive member between the guide structures, and a connection portion at least partially surrounded by the adhesive member, and a level of an upper surface of the connection portion is higher than a level of an uppermost portion of the guide structure.

### BRIEF DESCRIPTION OF THE FIGURES

The accompanying drawings are included to provide a further understanding of inventive concepts, and are incorporated in and constitute a part of this specification. The drawings illustrate some example embodiments of inventive concepts and, together with the description, serve to explain principles of inventive concepts. In the drawings:

FIG. 1A is a plan view of a semiconductor package according to some example embodiments;

FIG. 1B is a cross-sectional view taken along line A-A′ of FIG. 1A;

FIG. 1C is a cross-sectional view taken along line B-B′ of FIG. 1A;

FIG. 1D is an enlarged view of region E1 of FIG. 1A;

FIG. 1E is an enlarged view of region E2 of FIG. 1B;

FIG. 1F is a cross-sectional view of a semiconductor package according to some

example embodiments;

FIG. 2 is an enlarged view of a semiconductor package according to some example embodiments;

FIG. 3 is an enlarged view of a semiconductor package according to some example embodiments;

FIG. 4 is an enlarged view of a semiconductor package according to some example embodiments;

FIG. 5 is an enlarged view of a semiconductor package according to some example embodiments;

FIGS. 6A, 6B, 6C, 6D, 6E, 6F, and 6G are diagrams for describing a method for manufacturing a semiconductor package according to some example embodiments; and

FIG. 7 is a cross-sectional view of a semiconductor package according to some example embodiments.

### DETAILED DESCRIPTION

Hereinafter, a semiconductor device and methods for manufacturing the same according to some example embodiments of inventive concepts will be described in detail with reference to the drawings.

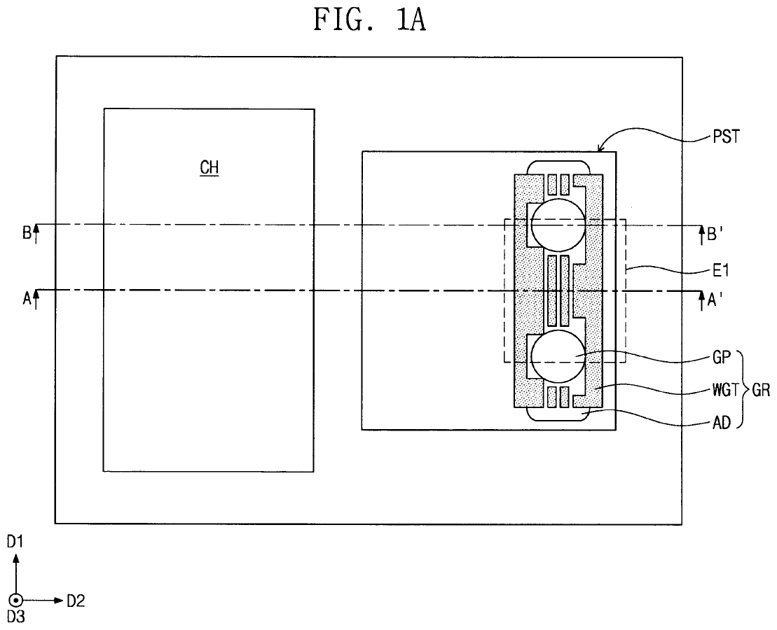

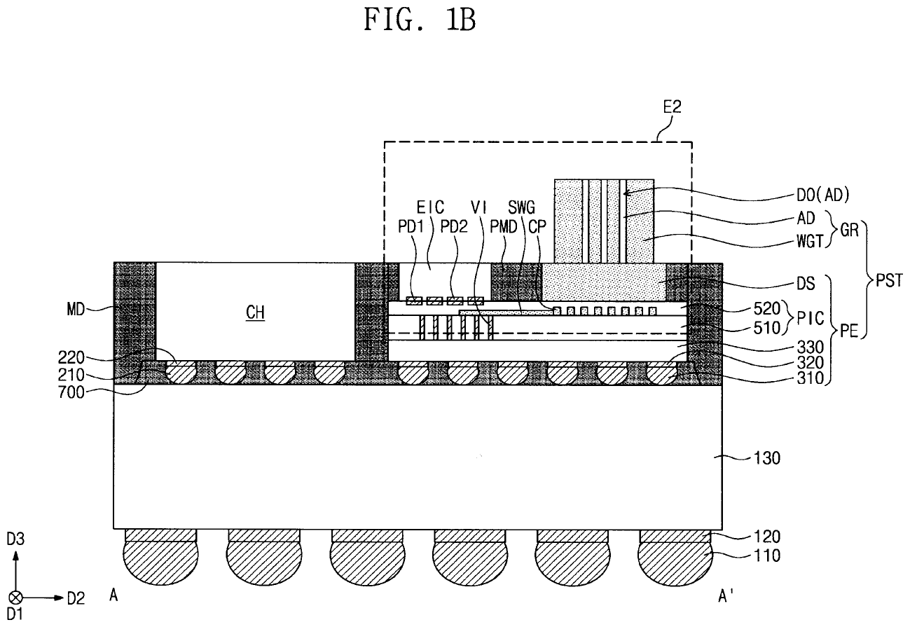

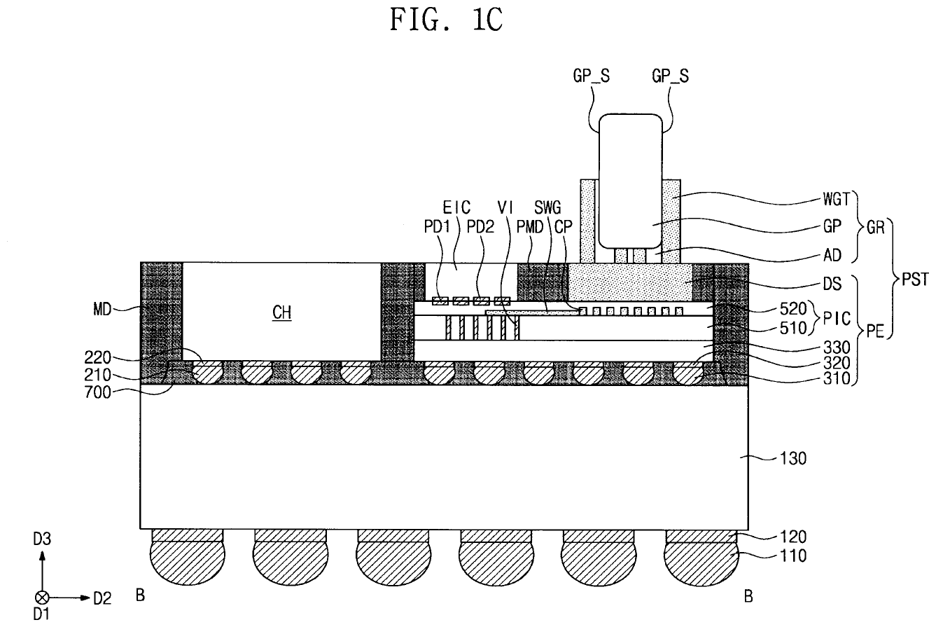

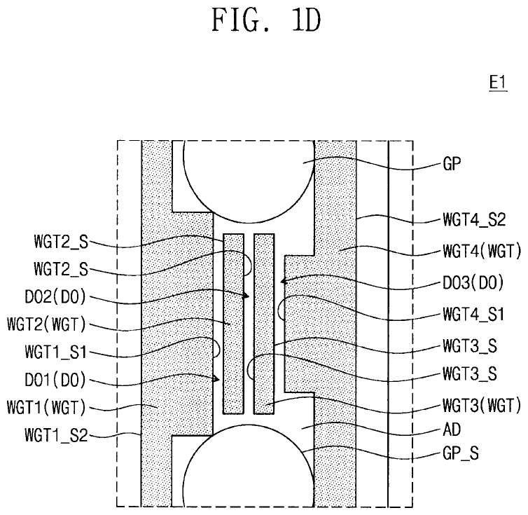

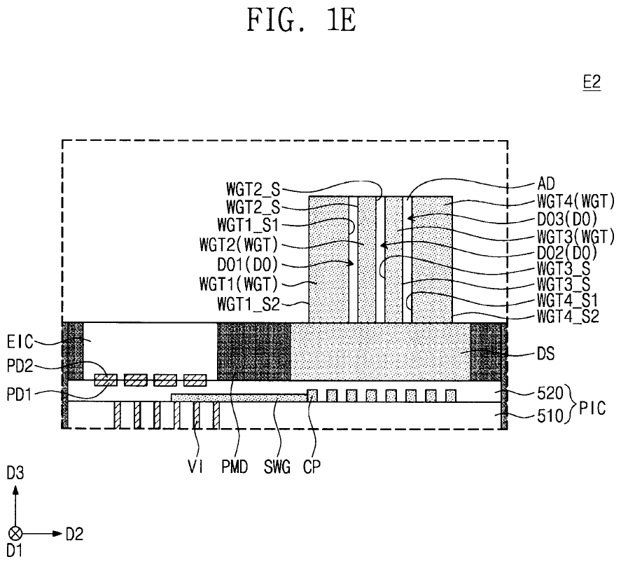

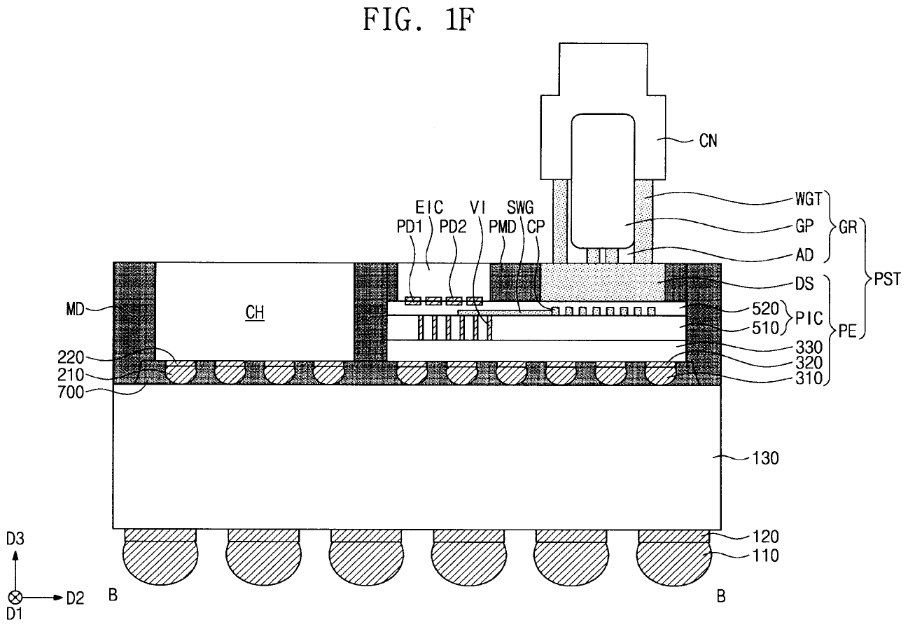

FIG. 1A is a plan view of a semiconductor package according to some example embodiments. FIG. 1B is a cross-sectional view taken along line A-A′ of FIG. 1A. FIG. 1C is a cross-sectional view taken along line B-B′ of FIG. 1A. FIG. 1D is an enlarged view of region E1 of FIG. 1A. FIG. 1E is an enlarged view of region E2 of FIG. 1B. FIG. 1F is a cross-sectional view of the semiconductor package according to some example embodiments.

Referring to FIGS. 1A to 1E, the semiconductor package may include first solder balls 110, second solder balls 210, first conductive pads 120, second conductive pads 220, an interposer substrate 130, a semiconductor chip CH, an underfill film 700, a molding film MD, and an optical structure PST.

The first solder balls 110 and the first conductive pads 120 may be provided. Each of the first conductive pads 120 may be disposed (for example, respectively disposed) on the first solder balls 110. The first solder ball 110 and the first conductive pad 120 may include, for example, a conductive material. For example, the first solder ball 110 and the first conductive pad 120 may include copper (Cu), but example embodiments are not limited thereto.

The interposer substrate 130 may be provided on the first conductive pads 120. The interposer substrate 130 may have a form of a plate expanded (for example, extending) along a plane defined by a first direction D1 and a second direction D2. The first direction D1 and the second direction D2 may cross each other. For example, the first direction D1 and the second direction D2 may be directions perpendicular to each other. According to some example embodiments, the interposer substrate 130 may be a reline substrate, but example embodiments are not limited thereto.

The semiconductor chip CH may be provided on the interposer substrate 130. The semiconductor chip CH may be mounted on the interposer substrate 130. The semiconductor chip CH may be or include, for example, a logic chip and/or memory chip. When the semiconductor chip CH is or includes a logic chip, the semiconductor chip CH may be or include, for example, an application specific integrated circuit (ASIC) and/or system-on-chip, but example embodiments are not limited thereto. When the semiconductor chip CH is or includes a memory chip, the semiconductor chip CH may be or include, for example, a high bandwidth memory (HBM) chip, but example embodiments are not limited thereto. For example, the logic chip may receive an order, data, signals, and/or the like from an external controller, and may transmit the received order, data, signals, and/or the like to a memory chip.

A number of the semiconductor chip CH may not be limited to what is illustrated, and the semiconductor chip CH may include a plurality of semiconductor chips CH. For example, the number of the semiconductor chips CH may be equal to or more than two. For example, the semiconductor chips CH may include a plurality of logic chips and/or a plurality of memory chips. The logic chip(s) may transmit data output from the memory chip(s) to an external controller. The logic chip(s) may include, for example a memory controller that controls the memory chip(s), and that inputs and/or outputs data, but example embodiments are not limited thereto.

The second solder balls 210 and the second conductive pads 220 may be provided between the semiconductor chip CH and the interposer substrate 130. The second conductive pad 220 may be provided on a lower surface of the semiconductor chip CH. Each of the second conductive pads 220 may be provided on the second solder ball 210. The second solder balls 210 may be in contact (for example, direct contact) with an upper surface of the interposer substrate 130. The second conductive pads 220 may be in contact (for example, direct contact) with a lower surface of the semiconductor chip CH. The second solder balls 210 and the second conductive pads 220 may connect (for example, electrically connect) the semiconductor chip CH and the interposer substrate 130. The second solder ball 210 and the second conductive pad 220 may include, for example, a conductive material. For example, the second solder ball 210 and the second conductive pad 220 may include copper (Cu), but example embodiments are not limited thereto.

The underfill film 700 may be provided on the interposer substrate 130. The underfill film 700 may be provided between the semiconductor chip CH and the interposer substrate 130, and/or between the optical structure PST and the interposer substrate 130. The underfill film 700 may surround or at least partially surround the second solder balls 210 and the second conductive pads 220. The underfill film 700 may include, for example, an insulating material. For example, the underfill film 700 may include an epoxy resin, but example embodiments are not limited thereto.

The molding film MD may be provided. The molding film MD may surround or at least partially surround sidewalls of the semiconductor chip CH and/or sidewalls of a circuit structure PE. An upper surface of the semiconductor chip CH and an upper surface of the circuit structure PE may be exposed (for example, at least partially exposed) through an upper surface of the molding film MD. The molding film MD may be in contact (for example, direct contact) with the semiconductor chip CH, the circuit structure PE, the interposer substrate 130, and/or the underfill film 700. The molding film MD may include, for example, an insulating material.

The optical structure PST may be provided on the interposer substrate 130. The optical structure PST may be mounted on the interposer substrate 130. The optical structure PST may include the circuit structure PE and a connection portion GP on the circuit structure PE.

The circuit structure PE may include third solder balls 310, third conductive pads 320, a reline layer 330, an optical integrated circuit PIC, an electronic integrated circuit EIC, a transfer structure DS, and a circuit molding film PMD.

The third solder balls 310 may be provided on the interposer substrate 130. The third solder balls 310 may be in contact with an upper surface of the interposer substrate 130. Each of the third conductive pads 320 may be provided on the third solder ball 310. The third conductive pads 320 may be in contact with a lower surface of the reline layer 330. The third solder balls 310 and the third conductive pads 320 may include a conductive material. For example, the third solder ball 310 and the third conductive pad 320 may include, for example, copper (Cu), but example embodiments are not limited thereto.

The reline layer 330 may be provided on the third conductive pads 320. The reline layer 330 may include a line therein. The reline layer 330 may be connected (for example, electrically connected) to the third solder balls 310 and/or the third conductive pads 320. The optical integrated circuit PIC may be connected (for example, electrically connected) to the interposer substrate 130 through (for example, by) the reline layer 330, the third solder balls 310 and/or the third conductive pads 320.

The optical integrated circuit PIC may include a substrate layer 510, and an element layer 520 on the substrate layer 510. The substrate layer 510 may be in contact (for example, direct contract) with an upper surface of the reline layer 330. The substrate layer 510 may be or include a semiconductor substrate. For example, the substrate layer 510 may include silicon, germanium, silicon-germanium, gallium-phosphor, or gallium-arsenic, but example embodiments are not limited thereto. According to some example embodiments, the substrate layer 510 may be a silicon-on-insulator (SOI) substrate, or a germanium-on-insulator (GOI) substrate., but example embodiments are not limited thereto.

The substrate layer 510 may include vias VI. The vias VI may connect the element layer 520 and the reline layer 330 of the optical integrated circuit PIC. Elements inside or on the element layer 520 may be connected to the reline layer 330 through the vias VI. The vias VI may include a conductive material. For example, the vias VI may include one or more metals, but example embodiments are not limited thereto.

The element layer 520 may include an inner waveguide portion SWG, couplers CP, and first connection pads PD1. The inner waveguide portion SWG and the couplers CP may be provided in the element layer 520. Light may move from the inner waveguide portion SWG to the couplers CP, or from the couplers CP to the inner waveguide portion SWG. For example, the coupler CP may be a grating coupler, but example embodiments are not limited thereto. For example, the coupler CP may form a grating on an end of the inner waveguide portion SWG, and may transmit and/or receive light by using (for example, utilizing) diffraction characteristics of light received through the inner waveguide portion SWG. According to some example embodiments, the coupler CP may be an evanescent coupler, but example embodiments are not limited thereto. The element layer 520 may include, for example, an insulating film surrounding the inner waveguide portion SWG and the couplers CP, but example embodiments are not limited thereto. For example, the insulating film may include an oxide, but example embodiments are not limited thereto.

The first connection pads PD1 may be provided in (or on) the element layer 520. The first connection pads PD1 may be exposed through (for example, exposed from or at least partially uncovered by) an upper surface of the element layer 520. The first connection pads PD1 may be electrically connected to elements (for example, inner elements) of the element layer 520. The first connection pads PD1 may include a conductive material. For example, the first connection pad PD1 may include one or more metals, but example embodiments are not limited thereto.

Although not shown, elements, for example, optical elements, that play various roles (for example, which may be configured to serve various functions) may be disposed in the element layer 520. For example, the optical elements may include elements such, for example, as a semiconductor laser, a light source, a light amplifier, an electrical signal amplifier, a light modulator, and/or a light detector. The optical elements may include one or more elements that act as a transceiver that receives external light into the optical integrated circuit PIC, and/or that emits light of the optical integrated circuit PIC to the outside.

The electronic integrated circuit EIC may be provided on the optical integrated circuit PIC. The electronic integrated circuit EIC may be in contact (for example, direct contact) with an upper surface of the element layer 520 of the optical integrated circuit PIC. The electronic integrated circuit EIC may include second connection pads PD2. The second connection pads PD2 may be exposed through a lower surface of the electronic integrated circuit EIC. Each of the second connection pads PD2 may be connected (for example, correspondingly connected) to the first connection pads PD1. The electronic integrated circuit EIC may be electrically connected to the optical integrated circuit PIC through (for example, by) the first connection pad PD1 and/or the second connection pads PD2. The electronic integrated circuit EIC may transmit electrical signals to the optical integrated circuit PIC, and/or receive electrical signals from the optical integrated circuit PIC.

The transfer structure DS may be provided on the element layer 520 of the optical integrated circuit PIC. The transfer structure DS may be in contact (for example, direct contact) with the upper surface of the element layer 520. The transfer structure DS may overlap or at least partially overlap with the couplers CP in the element layer 520 in a third direction D3. Accordingly, light received from the inner waveguide portion SWG may be transmitted (for example, vertically transmitted) to the transfer structure DS through the couplers CP. For example, the third direction D3 may be a vertical direction perpendicular to the first direction D1 and the second direction D2. A thickness of the transfer structure DS in the third direction D3 may be, for example, about 30 μm to about 300 μm, but example embodiments are not limited thereto.

The transfer structure DS may include a material that transmits light. For example, the transfer structure DS may include a semiconductor material. For example, the transfer structure DS may include silicon (Si), but example embodiments are not limited thereto.

The circuit molding film PMD may be provided. The circuit molding film PMD may surround or at least partially sidewalls of the electronic integrated circuit EIC and/or sidewalls of the transfer structure DS. An upper surface of the electronic integrated circuit EIC and/or an upper surface of the transfer structure DS may be exposed through (for example, exposed from or uncovered by) an upper surface of the circuit molding film PMD. The circuit molding film PMD may be in contact (for example, direct contact) with the electronic integrated circuit EIC, the transfer structure DS, and/or the element layer 520 of the optical integrated circuit PIC. The molding film MD may include an insulating material.

A connection GR may be provided on the transfer structure DS. The connection GR may include, for example, guide structures WGT, an adhesive member AD, and a connection portion GP.

The guide structures WGT may be provided on the transfer structure DS. Any or each of the guide structures WGT may extend in the first direction D1. A length of each of the guide structures WGT in the first direction D1 may be, for example, greater than a length thereof in the second direction D2, but example embodiments are not limited thereto. The guide structures WGT may be disposed spaced apart from each other in the second direction DR2. The guide structures WGT may be apart or spaced apart from the optical integrated circuit PIC. A lower surface of any or each the guide structures WGT may be in contact (for example, direct contact) with an upper surface of the transfer structure DS. The guide structures WGT may overlap or at least partially overlap with the couplers CP in the element layer 520 in the third direction D3. For example, the guide structures WGT may include at least one of glass (SiO₂) or silicon (Si), but example embodiments are not limited thereto.

The adhesive member AD may be provided between the guide structures WGT. The adhesive member AD may be interposed in (for example, fill or at least partially fill) any empty space(s) between the guide structures WGT. The adhesive member AD may include, for example, a pillarless material, but example embodiments are not limited thereto. For example, the adhesive member AD may include a pillarless epoxy-based material.

The adhesive member AD may include waveguide portions DO between sidewalls, of the guide structures WGT, that face each other. Each of the waveguide portions DO may extend in the third direction D3. Any or each of the waveguide portions DO may be connected to the upper surface of the transfer structure DS. Light may be transmitted between the optical integrated circuit PIC and an external device through the waveguide portions DO. A width of a waveguide portion DO in the second direction D2 may be, for example, at least about 2 μm, and at most about 300 μm, but example embodiments are not limited thereto.

The connection portion GP surrounded or at least partially surrounded by the guide structures WGT may be provided. The connection portion GP may be in contact (for example, direct contact) with the guide structures WGT and/or the adhesive member AD. The connection portion GP may extend in the third direction D3. An external device may be connected (for example, fixed) to the connection GR through (for example, by) the connection portion GP.

Referring to FIGS. 1D and 1E, the guide structures WGT may include, for example, a first guide structure WGT1, a second guide structure WGT2, a third guide structure WGT3, and a fourth guide structure WGT4. The first to fourth guide structures WGT1, WGT2, WGT3, and WGT4 may be sequentially spaced apart from each other in the second direction D2. The first guide structure WGT1 and the fourth guide structure WGT4 may be guide structures WGT disposed at the outermost sides among the guide structures WGT. The second guide structure WGT2 and the third guide structure WGT3 may be disposed between the first guide structure WGT1 and the fourth guide structure WGT4. The second guide structure WGT2 may be disposed between the first guide structure WGT1 and the third guide structure WGT3.

The first guide structure WGT1 and the fourth guide structure WGT4 may be, for example, in contact (for example, direct contact) with a sidewall GP_S of the connection portion GP. The sidewall GP_S of the connection portion GP may be, for example, apart or spaced apart from the second guide structure WGT2 and the third guide structure WGT3. A lower surface of the connection portion GP may be in contact (for example, direct contact) with an upper surface of the second guide structure WGT2 and/or an upper surface of the third guide structure WGT3.

The first guide structure WGT1 may include a first sidewall WGT1_S1 and a second sidewall WGT1_S2 on the opposite side of the first sidewall WGT1_S1. The second guide structure WGT2 may include sidewalls WGT2_S. The third guide structure WGT3 may include sidewalls WGT3_S. The fourth guide structure WGT4 may include a first sidewall WGT4_S1, and a second sidewall WGT4_S2 on the opposite side of the first sidewall WGT4_S1.

The first sidewall WGT1_S1 of the first guide structure WGT1, the sidewalls WGT2_S of the second guide structure WGT2, the sidewalls WGT3_S of the third guide structure WGT3, and the first sidewall WGT4_S1 of the fourth guide structure WGT4 may be in contact (for example, direct contact) with the adhesive member AD. The second sidewall WGT1_S2 of the first guide structure WGT1 and the second sidewall WGT4_S2 of the fourth guide structure WGT4 may be apart or spaced apart from the adhesive member AD. The second sidewall WGT1_S2 of the first guide structure WGT1 and the second sidewall WGT4_S2 of the fourth guide structure WGT4 may be outermost sidewalls among sidewalls of the guide structures WGT. The second sidewall WGT1_S2 of the first guide structure WGT1 and the second sidewall WGT4_S2 of the fourth guide structure WGT4 may be exposed or at least partially exposed. The first sidewall WGT1_S1 of the first guide structure WGT1 and one of the sidewalls WGT2_S of the second guide structure WGT2 may face each other. One of the sidewalls WGT2_S of the second guide structure WGT2 and one of the sidewalls WGT3_S of the third guide structure WGT3 may face each other. One of the sidewalls WGT3_S of the third guide structure WGT3 and the first sidewall WGT4_S1 of the fourth guide structure WGT4 may face each other.

A number of the guide structures WGT may not be limited to what is illustrated. For example, the number of the guide structures WGT may be at most 3, or at least 5.

The waveguide portions DO may include a first waveguide portion DO1, a second waveguide portion DO2, and a third waveguide portion DO3. The first waveguide portion DO1 may be provided between the first guide structure WGT1 and the second guide structure WGT2. The second waveguide portion DO2 may be provided between the second guide structure WGT2 and the third guide structure WGT3. The third waveguide portion DO3 may be provided between the third guide structure WGT3 and the fourth guide structure WGT4. The first waveguide portion DO1 may be defined by the first sidewall WGT1_S1 of the first guide structure WGT1 and a sidewall WGT2_S of the second guide structure WGT2.

A number of the waveguide portions DO may not be limited to what is illustrated. For example, the number of the waveguide portions DO may be at most 2, or at least 4.

An upper surface of the semiconductor chip CH, an upper surface of the molding film MD, an upper surface of the electronic integrated circuit EIC, an upper surface of the transfer structure DS, and/or an upper surface of the circuit molding film PMD may be coplanar or substantially coplanar with each other. For example, the upper surface of the semiconductor chip CH, the upper surface of the molding film MD, the upper surface of the electronic integrated circuit EIC, the upper surface of the transfer structure DS, and/or the upper surface of the circuit molding film PMD may be placed at a same or substantially same level.

A width of the optical integrated circuit PIC in the second direction D2 may be, for example, greater than a width of the transfer structure DS in the second direction D2. The width of the transfer structure DS in the second direction D2 may be greater than a width of the connection GR in the second direction D2, but example embodiments are not limited thereto.

A level of a lowermost portion of the connection GR may be higher than a level of an upper surface of the optical integrated circuit PIC. A level of an upper surface of the connection portion GP may be higher than a level of the uppermost portion of the guide structure WGT. A level of a lower surface of the connection portion GP may be higher than a level of the upper surface of the transfer structure DS.

Referring to FIG. 1F, a detachable connector CN may be, for example, provided on the connection GR. The detachable connector CN may be connected to an upper portion of the connection portion GP of the connection GR. The detachable connector CN may be fixed (for example, vertically fixed) to the connection GR by an upper portion of the connection portion GP. Accordingly, the detachable connector CN may be detached from or attached to the connection GR. The detachable connector CN may be connected to an external device. The external device may be connected to the optical structure PST through the detachable connector CN.

The semiconductor package according to some example embodiments may include the plurality of guide structures WGT including (for example, defining) the plurality of waveguide portions DO. Accordingly, the semiconductor package may be advantageous for high bandwidth data transmission.

The connection GR of the semiconductor package according to some example embodiments may include the connection portion GP extending in a direction perpendicular or substantially perpendicular to the optical integrated circuit PIC. Since the connection portion GP may be included, the connection GR may be vertically detached from or attached to the detachable connector CN, thereby preventing or reducing damage to the connection GR.

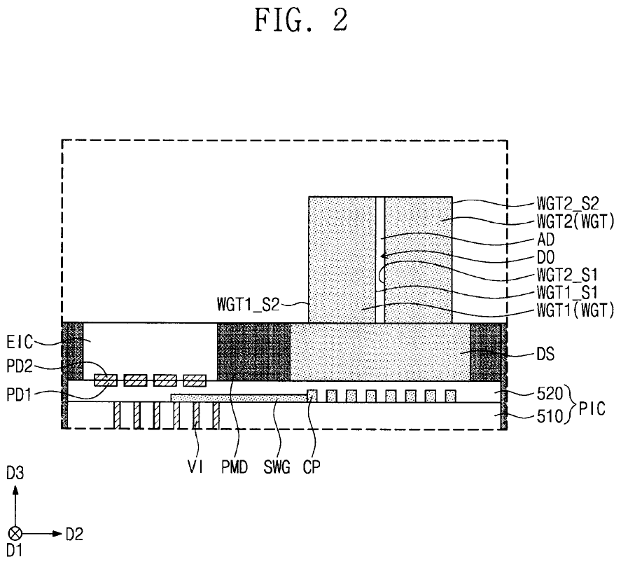

FIG. 2 is an enlarged view of a semiconductor package according to some example embodiments. The semiconductor package according to FIG. 2 may be similar to the semiconductor device according to FIGS. 1A to 1E, except for what is described below.

Referring to FIG. 2, an adhesive member AD may include one waveguide portion DO. Guide structures WGT may include a first guide structure WGT1 and a second guide structure WGT2.

The first guide structure WGT1 may include a first sidewall WGT1_S1 and a second sidewall WGT1_S2 on the opposite side of the first sidewall WGT1_S1. The second guide structure WGT2 may include a first sidewall WGT2_S1 and a second sidewall WGT2_S2 on the opposite side of the first sidewall WGT2_S1.

The first sidewall WGT1_S1 of the first guide structure WGT1 and the first sidewall WGT2_S1 of the second guide structure WGT2 may be in contact (for example, direct contact) with the adhesive member AD. The first sidewall WGT1_S1 of the first guide structure WGT1 and the first sidewall WGT2_S1 of the second guide structure WGT2 may be in contact with the adhesive member AD. The first sidewall WGT1_S1 of the first guide structure WGT1 and the first sidewall WGT2_S1 of the second guide structure WGT2 may face each other. The second sidewall WGT1_S2 of the first guide structure WGT1 and the second sidewall WGT2_S2 of the second guide structure WGT2 may be spaced apart from the adhesive member AD. The second sidewall WGT1_S2 of the first guide structure WGT1 and the second sidewall WGT2_S2 of the second guide structure WGT2 may be disposed on the outermost side of a connection GR.

The waveguide portion DO may be disposed or formed between the first guide structure WGT1 and the second guide structure WGT2. The waveguide portion DO may be defined by the first sidewall WGT1_S1 of the first guide structure WGT1 and the first sidewall WGT2_S1 of the second guide structure WGT2.

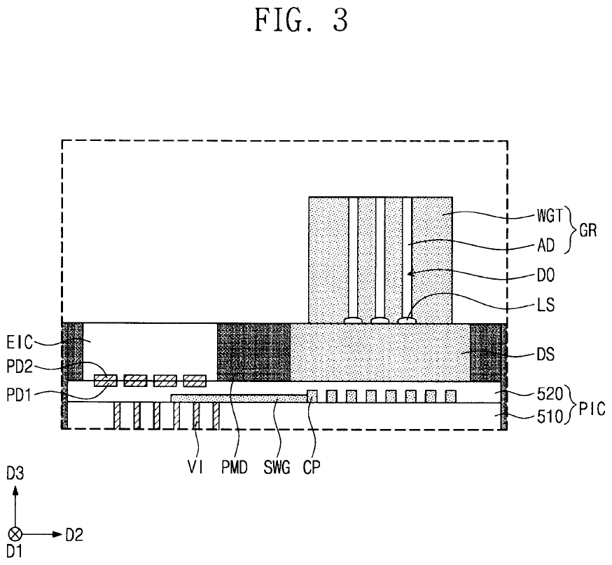

FIG. 3 is an enlarged view of a semiconductor package according to some example embodiments. The semiconductor package according to FIG. 3 may be similar to the semiconductor device according to FIGS. 1A to 1E, except for what is described below.

Referring to FIG. 3, lenses LS may be provided. The lenses LS may be disposed spaced apart from each other in the second direction D2. The lenses LS may be disposed between a transfer structure DS and a connection GR. The lenses LS may be in contact with an upper surface of the transfer structure DS. The lenses LS may be in contact (for example, direct contact) with guide structures WGT and/or an adhesive member AD. The lenses LS may overlap or at least partially overlap with couplers CP in the third direction D3. Any or each of the lenses LS may be connected to a waveguide portion DO. Each of the lenses LS may overlap or at least partially overlap with the waveguide portion DO in the third direction D3. The lens LS may focus and/or disperse light that moves from the transfer structure DS to the waveguide portions DO. The lens LS may focus and/or disperse light that moves from the waveguide portions DO to the transfer structure DS.

The semiconductor package according to some example embodiments may include the lenses LS between the transfer structure DS and the connection GR. Accordingly, the semiconductor package may focus and/or disperse light, thereby effectively or more effectively transmitting light.

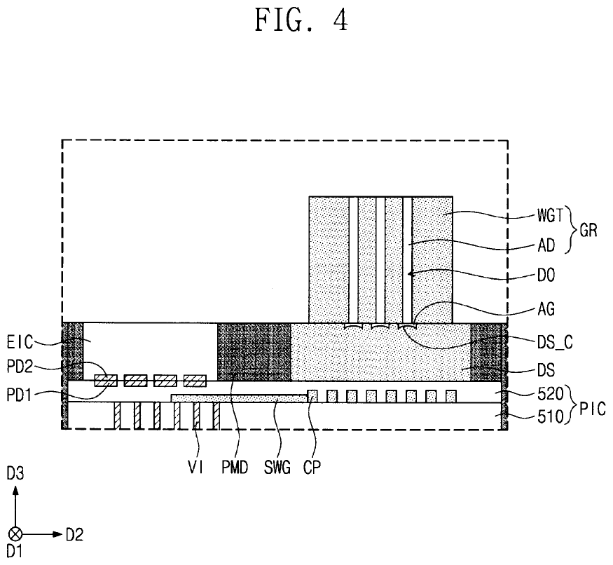

FIG. 4 is an enlarged view of a semiconductor package according to some example embodiments. The semiconductor package according to FIG. 4 may be similar to the semiconductor device according to FIGS. 1A to 1E, except for what is described below.

Referring to FIG. 4, air gaps AG may be provided or formed (for example, defined or at least partially defined) in the transfer structure DS. The transfer structure DS may include a curved surface DS_C spaced apart from a connection GR. A level of the curved surface DS_C of the transfer structure DS may be lower than a level of an upper surface of the transfer structure DS. The air gap AG may be provided (for example, defined or at least partially defined) between the curved surface DS_C of the transfer structure DS and the waveguide portion DO. The air gap AG may overlap or at least partially overlap with the waveguide portion DO in the third direction D3. The curved surface DS_C of the transfer structure DS may define or at least partially define a lower surface of the air gap AG. The curved surface DS_C of the transfer structure DS may be curved or substantially curved. The curved surface DS_C of the transfer structure DS may be, for example, concave or convex toward the optical integrated circuit PIC (for example, the curved surface DS_C may be understood as facing the optical integrated circuit PIC and concave or convex with respect thereto). The air gap AG may focus and/or disperse light that moves from the waveguide portions DO to and/or from the transfer structure DS.

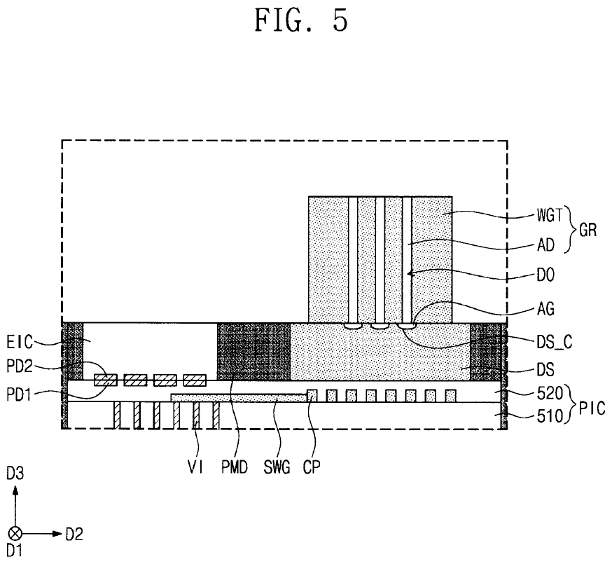

FIG. 5 is an enlarged view of a semiconductor package according to some example embodiments. The semiconductor package according to FIG. 5 may be similar to the semiconductor device according to FIGS. 1A to 1E, except for what is described below.

Referring to FIG. 5, air gaps AG may be provided in a transfer structure DS. The transfer structure DS may include a curved surface DS_C spaced apart from a connection GR. A level of the curved surface DS_C of the transfer structure DS may be lower than a level of an upper surface of the transfer structure DS. The air gap AG may be provided (for example, defined or at least partially defined) between the curved surface DS_C of the transfer structure DS and a waveguide portion DO. The air gap AG may overlap or at least partially overlap with the waveguide portion DO in the third direction D3. The curved surface DS_C of the transfer structure DS may define or at least partially define a lower surface of the air gap AG. The curved surface DS_C of the transfer structure DS may be curved or substantially curved. For example, the curved surface DS_C of the transfer structure DS may be convex toward the optical integrated circuit PIC, but example embodiments are not limited thereto. The air gap AG may, for example, focus and/or disperse light that moves from the waveguide portion DO to the transfer structure DS.

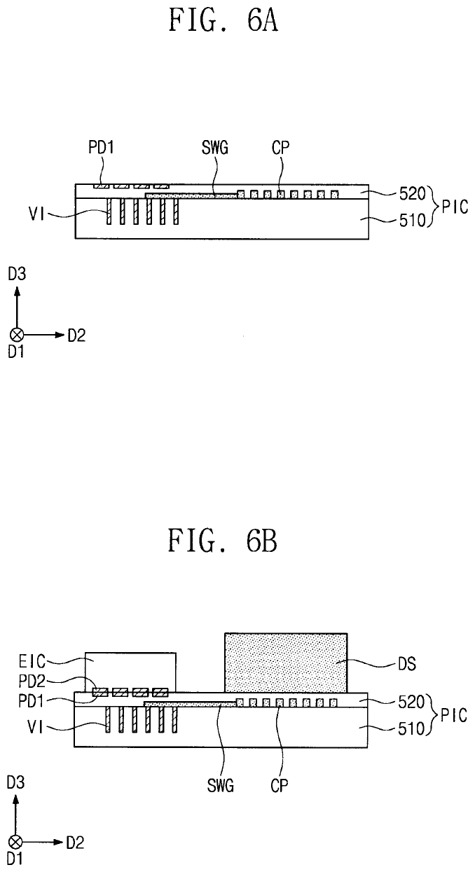

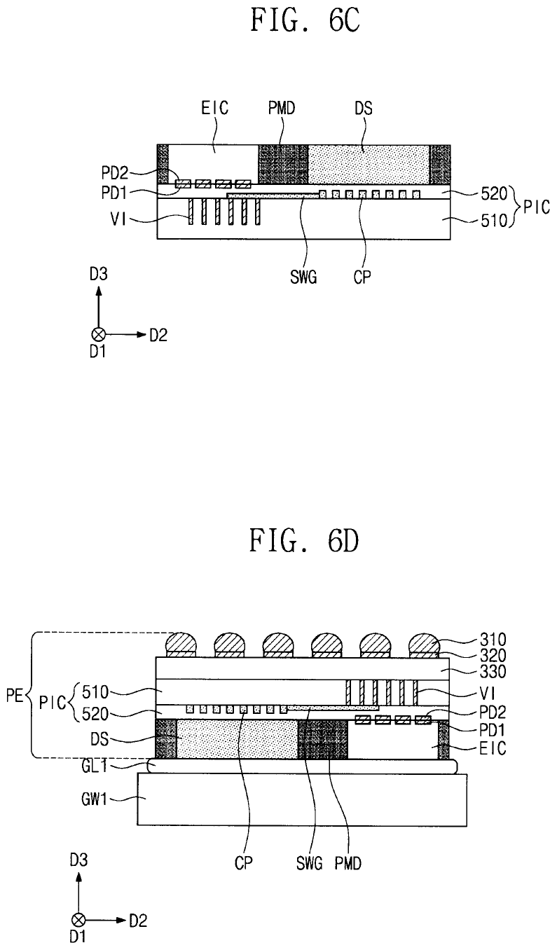

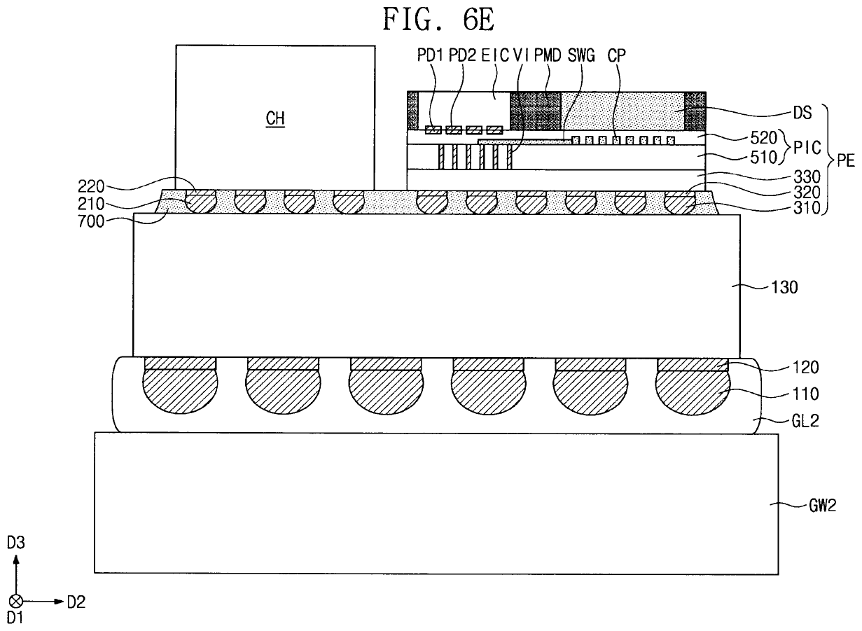

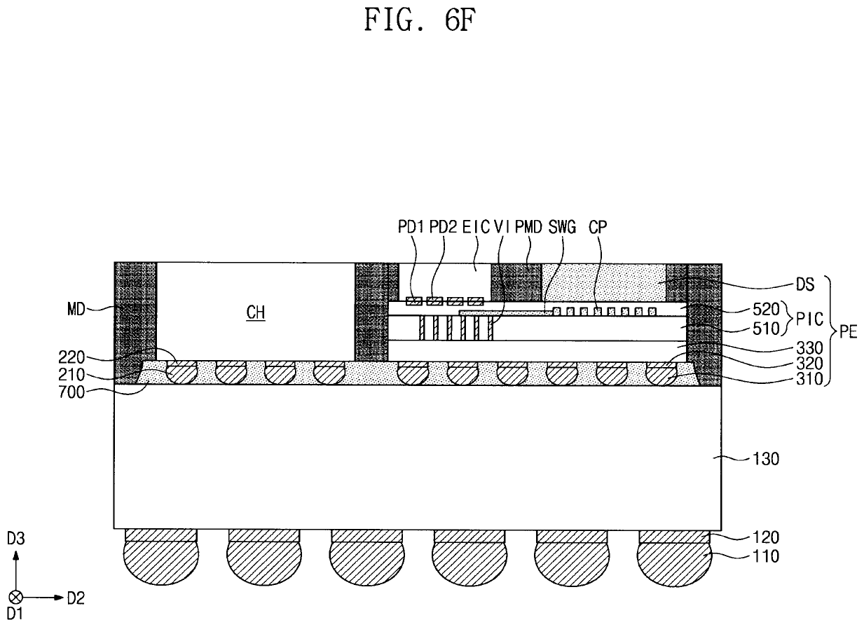

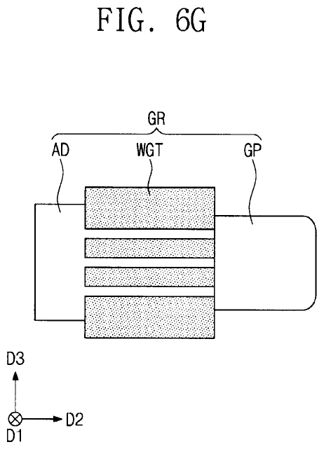

FIGS. 6A, 6B, 6C, 6D, 6E, 6F, and 6G are diagrams for describing methods for manufacturing a semiconductor package according to some example embodiments. FIGS. 6A to 6F may correspond to, for example, FIG. 1B.

Referring to FIG. 6A, an optical integrated circuit PIC may be formed. A substrate layer 510 of the optical integrated circuit PIC may be formed. Vias VI may be formed inside the substrate layer 510. An element layer 520 including an inner waveguide portion SWG, couplers CP, and first connection pads PD1, may be formed on the substrate layer 510.

Referring to FIG. 6B, an electronic integrated circuit EIC may be formed on the optical integrated circuit PIC. The electronic integrated circuit EIC may be formed on the optical integrated circuit PIC, for example through (for example, by) a thermal compression process, but example embodiments are not limited thereto. In some example embodiments, a second connection pad PD2 of the electronic integrated circuit EIC may be bonded to the first connection pad PD1 of the optical integrated circuit PIC through (for example, by), for example a hybrid Cu bonding process, but example embodiments are not limited thereto.

A transfer structure DS may be formed on the optical integrated circuit PIC. A level of an upper surface of the transfer structure DS may or may not be higher than a level of an upper surface of the electronic integrated circuit EIC. The transfer structure DS may be, for example, bonded to the optical integrated circuit PIC. In some example embodiments, a lower surface of the transfer structure DS may be bonded to an upper surface of the optical integrated circuit PIC through, for example, an oxide bonding process, but example embodiments are not limited thereto.

Referring to FIG. 6C, a circuit molding film PMD may be formed. The electronic integrated circuit EIC and the transfer structure DS may be surrounded or at least partially surrounded by the circuit molding film PMD. The circuit molding film PMD may cover or at least partially cover, the electronic integrated circuit EIC, the transfer structure DS, and/or the upper surface of the optical integrated circuit PIC.

The circuit molding film PMD may be partially removed or at least partially removed. The circuit molding film PMD may be partially removed until or such that the electronic integrated circuit EIC and the optical integrated circuit PIC are exposed (for example, at least partially exposed). When the circuit molding film PMD is partially removed, an upper portion of the transfer structure DS may also be removed therewith. Accordingly, as a result, the upper surface of the electronic integrated circuit EIC, the upper surface of transfer structure DS, and an upper surface of the circuit molding film PMD may be coplanar with each other. In some example embodiments, a portion of the circuit molding film PMD, and an upper portion of the of the transfer structure DS may be removed through, for example, a grinding process, but example embodiments are not limited thereto.

Referring to FIG. 6D, a first substrate adhesive member GL1 and a first glass substrate GW1 may be formed. The first substrate adhesive member GL1 may be formed on the upper surface of the electronic integrated circuit EIC, the upper surface of the optical integrated circuit PIC, and/or the upper surface of the circuit molding film PMD. The first glass substrate GW1 may be formed on the first substrate adhesive member GL1. The first glass substrate GW1 and the semiconductor package may be connected (for example, bonded) to each other by the first substrate adhesive member GL1. The first glass substrate GW1 may be turned over (for example, turned upside down along with features connected thereto). Accordingly, the substrate layer 510 of the optical integrated circuit PIC may be disposed on top (for example, understood as being on top of element layer 520). An upper portion of the substrate layer 510 of the optical integrated circuit PIC may be removed or at least partially removed. The upper portion of the substrate layer 510 of the optical integrated circuit PIC may be removed or at least partially removed until the vias VI are exposed. In some example embodiments, the upper portion of the substrate layer 510 of the optical integrated circuit PIC may be removed or at least partially removed through (for example, by using), for example, a grinding process, but example embodiments are not limited thereto.

A reline layer 330 may be formed on the substrate layer 510 of the optical integrated circuit PIC. Third conductive pads 320 may be formed on the reline layer 330. Third solder balls 310 may be formed on any or each of the third conductive pads 320. Accordingly, a circuit structure PE including, for example, the third solder balls 310, the third conductive pads 320, the reline layer 330, the optical integrated circuit PIC, the electronic integrated circuit EIC, the transfer structure DS, and the circuit molding film PMD may be defined, but example embodiments are not limited thereto.

Referring to FIG. 6E, first solder balls 110, first conductive pads 120, and an interposer substrate 130 may be formed. A second substrate adhesive member GL2 covering or at least partially covering the first solder balls 110 and/or the first conductive pads 120 may be formed. A second glass substrate GW2 may be formed on the second substrate adhesive member GL2. The second glass substrate GW2 and the interposer substrate 130 may be connected (for example, bonded) to each other by the second substrate adhesive member GL2. The second glass substrate GW2 may be turned over (for example, turned upside down along with features connected thereto). Accordingly, an upper surface of the interposer substrate 130 may be exposed.

A semiconductor chip CH may be formed. Second conductive pads 220 may be formed on a lower surface of the semiconductor chip CH. Second solder balls 210 may be formed on any or each of the second conductive pads 220.

The semiconductor chip CH and the circuit structure PE may be mounted on the interposer substrate 130. The semiconductor chip CH may be mounted on an upper surface of the interposer substrate 130 through (for example, by) the second solder balls 210. The first glass substrate GW1 may be turned over again. Accordingly, the third solder balls 310 may face the upper surface of the interposer substrate 130. The circuit structure PE may be mounted on the upper surface of the interposer substrate 130 through the third solder balls 310. After the circuit structure PE is mounted, the first substrate adhesive member GL1 and the first glass substrate GW1 may be removed. In some example embodiments, the second solder balls 210 and the third solder balls 310 may be fixed to the upper surface of the interposer substrate 130 through, for example, a reflow process, but example embodiments are not limited thereto.

An underfill film 700 may be formed. Any empty space or spaces between the semiconductor chip CH and the interposer substrate 130 and/or between the circuit structure PE and the interposer substrate 130 may be filled or at least partially with the underfill film 700.

Referring to FIG. 6F, the second substrate adhesive member GL2 and the second glass substrate GW2 may be removed. A molding film MD covering the semiconductor chip CH and the circuit structure PE may be formed. The molding film MD may cover or at least partially cover an upper surface of the semiconductor chip CH and/or an upper surface of the circuit structure PE.

The molding film MD may be removed, for example, partially removed. The molding film MD may be partially removed until the semiconductor chip CH and the circuit structure PE are exposed (for example, at least partially exposed). When the molding film MD is partially removed, an upper portion of the semiconductor chip CH may be removed therewith. Accordingly, as a result, the upper surface of the semiconductor chip CH, the upper surface of the circuit structure PE, and the upper surface of the molding film MD may be coplanar or substantially coplanar with each other, but example embodiments are not limited thereto. In some example embodiments, the molding film MD may be partially removed through, for example, a grinding process, but example embodiments are not limited thereto.

Referring to FIG. 6G, guide structures WGT may be formed. The guide structures WGT may be formed by performing, for example, an ion-exchange process on, for example, a dummy glass or dummy silicon (Si), but example embodiments are not limited thereto.

An adhesive member AD and a connection portion GP may be formed. The adhesive member AD may fill (for example, at least partially fill) a space between the guide structures WGT. The connection portion GP may be inserted into an empty space between the guide structures WGT. The connection portion GP may be fixed by the adhesive member AD that fills the space between the guide structures WGT. The adhesive member AD and the connection portion GP may be formed as to define or at least partially define a connection GR.

Referring back to FIGS. 1B and 1E, the connection GR may be bonded to the circuit structure PE. The connection GR may be connected (for example, bonded) to the upper surface of the transfer structure DS of the circuit structure PE. In some example embodiments, the connection GR may be bonded to the upper surface of the transfer structure DS through (for example, by using) for example, a laser welding process, but example embodiments are not limited thereto. In other example embodiments, the connection GR may be, for example, bonded to the upper surface of the transfer structure DS by the adhesive member AD, but example embodiments are not limited thereto.

The methods for manufacturing a semiconductor package according to some example embodiments may include the transfer structure DS. Accordingly, in, for example, a grinding process, removal of an upper portion of the electronic integrated circuit EIC and/or an upper portion of the semiconductor chip CH may be reduced, optimized, or minimized due to a step or steps including the transfer structure DS, accordingly increasing process efficiency.

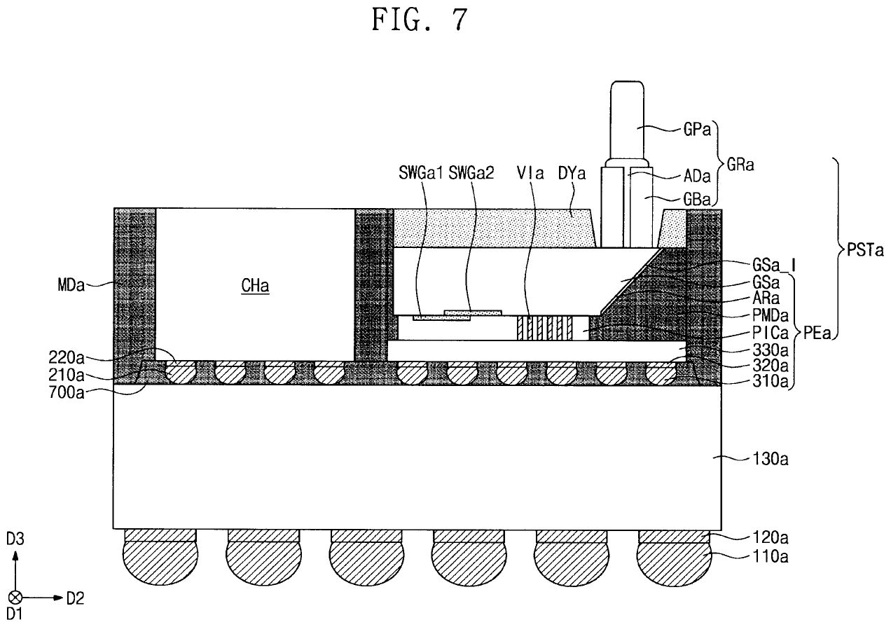

FIG. 7 is a cross-sectional view of a semiconductor package according to some example embodiments.

Referring to FIG. 7, the semiconductor package may include first solder balls 110a, first conductive pads 120a, an interposer substrate 130a, second solder balls 210a, second conductive pads 220a, a semiconductor chip Cha, an underfill film 700a, and/or a molding film Mda. The first solder balls 110a, the first conductive pads 120a, the interposer substrate 130a, the second solder balls 210a, the second conductive pads 220a, the semiconductor chip Cha, the underfill film 700a, and the molding film Mda of FIG. 7 may be the same, substantially the same, or similar to the first solder balls 110, the first conductive pads 120, the interposer substrate 130, the second solder balls 210, the second conductive pads 220, the semiconductor chip CH, the underfill film 700, and the molding film MD of FIGS. 1A to 1E.

An optical structure PSTa may be provided on the interposer substrate 130a. The optical structure PSTa may be mounted on the interposer substrate 130a. The optical structure PSTa may include a circuit structure Pea and a connection Gra.

The circuit structure Pea may include third solder balls 310a, third conductive pads 320a, a reline layer 330a, an optical integrated circuit PICa, a circuit molding film PMDa, a first glass structure Gsa, a coating layer Ara, and/or a dummy structure 24ay. The third solder balls 310a, the third conductive pads 320a, the reline layer 330a, and the circuit molding film PMDa of the circuit structure Pea may be the same as, substantially the same as, or similar to the third solder balls 310, the third conductive pads 320, the reline layer 330, and the circuit molding film PMD of FIGS. 1A to 1E.

The optical integrated circuit PICa may include vias Via and a first inner waveguide portion SWGa1. The vias Via of FIG. 7 may be the same as, substantially the same as, or similar to the vias VI of FIGS. 1A to 1E. The first inner waveguide portion SWGa1 may be exposed through an upper surface of the optical integrated circuit PICa.

The first glass structure Gsa may be provided on the optical integrated circuit PICa. The first glass structure Gsa may include a second inner waveguide portion SWGa2. Light may move from the optical integrated circuit PICa to the first glass structure Gsa through the first inner waveguide portion SWGa1 and the second inner waveguide portion SWGa2. The first glass structure Gsa may include or have a slope (for example, a sloped surface) GSa_I. The slope GSa_I of the first glass structure GSa may be inclined with respect to a lower surface of the first glass structure GSa.

In some example embodiments, the first inner waveguide portion SWGa1 and the second inner waveguide portion SWGa2 may transmit light to the first glass structure GSa through (for example, by), for example, an evanescent coupling method, but example embodiments are not limited thereto.

A coating layer ARa may be provided between the first glass structure GSa and the circuit molding film PMDa. The coating layer ARa may be in contact with the slope GSa_I of the first glass structure GSa. The coating layer ARa may be inclined with respect to the optical integrated circuit PICa. The coating layer ARa may be, for example, a layer on which an antireflective material is applied. For example, the coating layer ARa may include, for example, SiO₂, TiO₂, or LiNbO₃, but example embodiments are not limited thereto, In the optical integrated circuit PICa, light that passes through the first glass structure GSa may be reflected on the coating layer ARa to be transmitted to the connection GRa.

The circuit molding film PMDa may surround or at least partially surround the optical integrated circuit PICa and/or the first glass structure GSa. The circuit molding film PMDa may be in contact (for example, direct contact) with the reline layer 330a, the optical integrated circuit PICa, the first glass structure GSa, and/or the coating layer ARa.

The dummy structure DYa may be provided on the first glass structure GSa. The dummy structure DYa may at least partially expose an upper surface of the first glass structure GSa. For example, the dummy structure DYa may include silicon (Si), but example embodiments are not limited thereto.

The connection GRa may be provided on the circuit structure PEa. The connection GRa may be disposed on, for example, an exposed portion of the upper surface of the first glass structure GSa.

The connection GRa may include second glass structures GBa, an adhesive member ADa, and a connection portion GPa. The second glass structures GBa may be connected to the exposed portion of the upper surface of the first glass structure GSa. Light that passes through the first glass structure GSa and then is reflected on the coating layer ARa may be transmitted to the second glass structures GBa.

The adhesive member ADa may be provided between sidewalls, of the second glass structures GBa, facing each other. The connection portion GPa may be provided on the adhesive member ADa. An external device may be vertically disposed (for example, fixed) onto the connection GRa through the connection portion GPa. Accordingly, an external device may be detached from or attached to the connection GRa.

A semiconductor package according to some example embodiments of inventive concepts may include a plurality of guide structures including a plurality of waveguide portions. Accordingly, the semiconductor package may be advantageous with respect to high bandwidth data transmission.

An optical structure of the semiconductor package according to some example embodiments of inventive concepts may include an optical integrated circuit and a connection portion extending in a direction perpendicular to the optical integrated circuit. As the connection portion is included, the optical structure may be or at least partially be vertically detached from or attached to an external connector, thereby preventing or reducing damage of the optical structure.

The semiconductor package according to some example embodiments of inventive concepts may include lenses between a transfer structure and the connection. Accordingly, light may be focused and/or dispersed, thereby efficiently transmitting light.

Methods for manufacturing a semiconductor package according to some example embodiments of inventive concepts may include a transfer structure. Accordingly, in a grinding process, removal an upper portion of an electronic integrated circuit and/or an upper portion of a semiconductor chip may be reduced, optimized, or minimized removed due to a step including the transfer structure, accordingly increasing process efficiency.

Although example embodiments of the present inventive concepts have been described, it is understood by one of ordinary skill in the art that the present inventive concepts should not be limited to these example embodiments but various changes and modifications can be made by one ordinary skilled in the art within the spirit and scope of the present invention as hereinafter claimed.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A semiconductor package comprising:
an optical integrated circuit including a coupler;
an electronic integrated circuit connected to the optical integrated circuit;
a transfer structure in contact with an upper surface of the optical integrated circuit; and
a connection on the transfer structure,
wherein the connection includes
guide structures extending in a first direction and spaced apart from each other in a second direction, the second direction perpendicular to the first direction;
an adhesive member between the guide structures; and
a connection portion at least partially surrounded by the adhesive member,
the adhesive member includes a waveguide portion, the waveguide portion between sidewalls of the guide structures that face each other, and
the waveguide portion is connected to the transfer structure.

2. The semiconductor package of claim 1, wherein an upper surface of the transfer structure is coplanar with an upper surface of the electronic integrated circuit.

3. The semiconductor package of claim 1, further comprising:
a lens in contact with an upper surface of the transfer structure,
wherein the lens is between the waveguide portion and the transfer structure.

4. The semiconductor package of claim 1, wherein the guide structures comprise silicon (Si).

5. The semiconductor package of claim 1, wherein the guide structures comprise glass (SiO₂).

6. The semiconductor package of claim 1, wherein the coupler at least partially overlaps with the waveguide portion.

7. The semiconductor package of claim 1, wherein the guide structure is spaced apart from the optical integrated circuit.

8. The semiconductor package of claim 1, wherein the guide structures comprise a first guide structure and a second guide structure,
the first guide structure and the second guide structures each comprise
a first sidewall in contact with the adhesive member, and
a second sidewall spaced apart from the adhesive member,
the first sidewall of the first guide structure and the first sidewall of the second guide structure face each other, and
the waveguide portion is at least partially defined by
the first sidewall of the first guide structure, and
the first sidewall of the second guide structure.

9. The semiconductor package of claim 1, wherein the transfer structure comprises
an upper surface in contact with the guide structure, and
a curved surface spaced apart from the guide structure,
a level of the curved surface of the transfer structure is lower than a level of the upper surface of the transfer structure, and
an airgap is at least partially defined between the curved surface of the transfer structure and the waveguide portion.

10. The semiconductor package of claim 9, wherein the curved surface of the transfer structure is concave toward the optical integrated circuit.

11. The semiconductor package of claim 9, wherein the curved surface of the transfer structure is convex toward the optical integrated circuit.

12. The semiconductor package of claim 1, wherein a thickness of the transfer structure in a third direction is at least 30 μm and at most 300 μm, the third direction perpendicular to the first direction and to the second direction.

13. A semiconductor package comprising:
an optical integrated circuit including a coupler;
an electronic integrated circuit connected to the optical integrated circuit;
a transfer structure on the optical integrated circuit; and
a connection on the transfer structure,
wherein the connection includes
guide structures extending in a first direction;
an adhesive member between the guide structures; and
a connection portion at least partially surrounded by the adhesive member, and the transfer structure includes a semiconductor material and is in contact with an upper surface of the optical integrated circuit, and
a lower surface of the guide structure.

14. The semiconductor package of claim 13, wherein the guide structures comprise a first guide structure, a second guide structure, a third guide structure, and a fourth guide structure spaced apart from each other in a second direction, the second direction perpendicular to the first direction,
the second guide structure is between the first guide structure and the third guide structure,
the first guide structure and the fourth guide structure are in contact with a sidewall of the connection portion, and
the second guide structure and the third guide structure are spaced apart from the sidewall of the connection portion.

15. The semiconductor package of claim 14, wherein the adhesive member comprises
a first waveguide portion between a sidewall of the first guide structure and a sidewall of the second guide structure;
a second waveguide portion between a sidewall of the second guide structure and a sidewall of the third guide structure; and
a third waveguide portion between a sidewall of the third guide structure and a sidewall of the fourth guide structure.

16. The semiconductor package of claim 14, wherein an upper surface of the second guide structure and an upper surface of the third guide structure are in contact with a lower surface of the connection portion.

17. The semiconductor package of claim 13, wherein a width of the transfer structure in a second direction is greater than a width of the connection in the second direction, the second direction perpendicular to the first direction.

18. The semiconductor package of claim 13, wherein the transfer structure is at a same level as the electronic integrated circuit.

19. A semiconductor package comprising:
a first solder ball;
an interposer substrate on the first solder ball;
a semiconductor chip on the interposer substrate; and
an optical structure spaced apart from the semiconductor chip and on the interposer substrate,
wherein the optical structure includes
a second solder ball;
a reline substrate on the second solder ball;
an optical integrated circuit on the reline substrate;
an electronic integrated circuit connected to the optical integrated circuit;
a transfer structure in contact with an upper surface of the optical integrated circuit; and
a connection on the transfer structure,
the connection includes
guide structures extending in a first direction and spaced apart from each other in a second direction, the second direction perpendicular to the first direction;
an adhesive member between the guide structures; and
a connection portion at least partially surrounded by the adhesive member, and
a level of an upper surface of the connection portion is higher than a level of an uppermost portion of the guide structure.

20. The semiconductor package of claim 19, wherein an upper surface of the semiconductor chip, an upper surface of the electronic integrated circuit, and an upper surface of the transfer structure are coplanar with each other.
